(19) United States
(12) Patent Application Publication
(10) Pub. No.: US 2012/0087071 A1
(43) Pub. Date: Apr. 12, 2012

(54) LATCH STRUCTURE AND ELECTRONIC DEVICE

(75) Inventors: JUI-CHING YANG, Shulin City (TW); CHING-FENG HSIEH, Taipei City 108 (TW)

(73) Assignee: ASKEY COMPUTER CORP., Taipei (TW)

(21) Appl. No.: 12/955,977

(22) Filed: Nov. 30, 2010

(30) Foreign Application Priority Data
Oct. 8, 2010 (TW) 099134357

(51) Int. Cl. H05K 7/00; E05C 1/08

(52) U.S. Cl. 361/679.01; 292/179

(57) ABSTRACT

A latch structure prevents separation of first and second bodies of an electronic device which might otherwise occur as a result of a fall, requires little force to operate, and serves to switch a coupling status of the first and second bodies of the electronic device. The first body has a receiving unit and a coupling unit. The second body has an L-shaped groove. A base of the latch structure has a casing slidable in the receiving unit and a resilient element for providing a resilient restoring force. The casing has a protruding member for coupling with the L-shaped groove. A resilient coupling unit of the latch structure is disposed on the base and configured to engage the coupling unit.

### CROSS-REFERENCE TO RELATED APPLICATION

This non-provisional application claims priority under 35 U.S.C. §119(a) on Patent Application No(s). 099134357 filed in Taiwan, R.O.C. on Oct. 8, 2010, the entire contents of which are hereby incorporated by reference.

### FIELD OF THE TECHNOLOGY

The present invention relates to latch structures and electronic devices having the latch structures, and more particularly, to a latch structure and an electronic device having the latch structure such that the latch structure prevents separation of first and second bodies of the electronic device which might otherwise occur as a result of a fall and requires little force to operate.

### BACKGROUND

People nowadays are all-inclusive users of electronic devices, especially portable electronic devices, such as mobile phones, personal digital assistants (PDA), or portable navigators. FIGS. 1 through 3 are an exploded view and a schematic view of a conventional latch structure and a main body of an electronic device, and a schematic view of the main body, the conventional latch structure, and a battery before assembly. As shown in the drawings, an electronic device having a conventional latch structure 3 essentially comprises a main body 1 and a battery 2. The conventional latch structure 3 serves to couple together or separate the main body 1 and the battery 2. The main body 1 essentially comprises a cover 11 and a carrier 12. The carrier 12 has a receiving chamber 121 and a plurality of coupling slots 122. The cover 11 has a through hole 111 and is configured to cover the receiving chamber 121 so as to form a receiving unit 13. One side of the battery 2 has an L-shaped groove 21. The other side of the battery 2 has a plurality of L-shaped coupling elements 22. The L-shaped coupling elements 22 are configured to couple with the coupling slots 122, respectively. The conventional latch structure 3 is resiliently slidable inside the receiving unit 13. The conventional latch structure 3 essentially comprises a resilient spring 32 and a casing 31 having an opening 311. Disposed on the casing 31 are a pressing block 312 and a protruding member 313 coupled to the L-shaped groove 21. One end of the resilient spring 32 abuts against an inner wall of the casing 31. The other end of the resilient spring 32 penetrates the opening 311 before abutting against an inner wall of the receiving unit 13. The pressing block 312 is exposed from the through hole 111 of the cover 11. Referring to FIGS. 3 through 5, there are shown a schematic view of the main body, the conventional latch structure, and a battery before assembly, and schematic views of the main body, the conventional latch structure, and the battery after assembly. As shown in the drawings, to couple together the main body 1 and the battery 2, it is necessary to take the following steps: press the pressing block 312 to thereby move the conventional latch structure 3 laterally and compress the resilient spring 32; insert the L-shaped coupling elements 22 of the battery 2 into the coupling slots 122 of the main body 1, respectively; cover the main body 1 with the battery 2 so as to enable the protruding member 313 of the conventional latch structure 3 to pass through one end of the L-shaped groove 21; and release the pressing block 312 to enable the conventional latch structure 3 to restore the position of the resilient spring 32 and enable the protruding member 313 of the conventional latch structure 3 to move to the other end of the L-shaped groove 21 so as to couple the main body 1 and the battery 2 together.

To prevent separation of the main body 1 and the battery 2 of the electronic device following a fall, it is typical for the conventional latch structure 3 to be equipped with strong said resilient spring 32, such that the resilient spring 32 abuts against the casing 31 forcefully to enable the casing 31 to be fixed in position. As a result, the conventional latch structure 3 effectively fixes the battery 2 to the main body 1. However, it is inconvenient and laborious to separate the main body 1 and the battery 2, because doing so entails moving the conventional latch structure 3 laterally to move the protruding member 313 of the conventional latch structure 3 to one end of the L-shaped groove 21.

Accordingly, it is imperative to invent a latch structure and an electronic device having the latch structure such that the latch structure prevents separation of first and second bodies of the electronic device which might otherwise occur as a result of a fall and requires little force to operate.

### SUMMARY

In view of the drawbacks of the prior art, it is an objective of the present invention to provide a latch structure and an electronic device having the latch structure such that the latch structure prevents separation of a first body and a second body of the electronic device which might otherwise occur as a result of a fall and requires little force to operate.

In order to achieve the above and other objectives, the present invention provides, in a first aspect, a latch structure for switching a coupling status of a first body and a second body of an electronic device, the first body having a receiving unit and a coupling unit, and the second body having an L-shaped groove, the latch structure comprising: a base having a casing and a resilient element, the casing being received in the receiving unit and slidable within the receiving unit in a first direction, the resilient element abutting against an inner wall of the receiving unit and the casing to thereby exert a resilient restoring force upon the casing according to the sliding of the casing, the casing having a protruding member for coupling with the L-shaped groove so as to couple the first body and the second body together; and a resilient coupling unit disposed on the base and configured to engage the coupling unit.

The present invention provides, in a second aspect, an electronic device comprising: a first body having a receiving unit and a coupling unit; a second body having an L-shaped groove; a base having a casing and a resilient element, the casing being received in the receiving unit and slidable within the receiving unit in a first direction, the resilient element abutting against an inner wall of the receiving unit and the casing so as to exert a resilient restoring force upon the casing according to the sliding of the casing, the casing having a protruding member protruding therefrom for coupling with the L-shaped groove so as to couple the first body and the second body together; and a resilient coupling unit disposed on the base and configured to engage the coupling unit.

Accordingly, the present invention provides a latch structure and an electronic device having the latch structure such that the latch structure prevents separation of first and second bodies of the electronic device which might otherwise occur as a result of a fall and requires little force to operate.

### BRIEF DESCRIPTION OF THE DRAWINGS

A detailed description of further features and advantages of the present invention is given below so that a person skilled in the art can understand and implement the technical contents of the present invention and readily comprehend the objectives, features, and advantages thereof by reviewing the disclosure of the present specification and the appended claims in conjunction with the accompanying drawings, in which:

FIG. 1 is an exploded view of a conventional latch structure and a main body of an electronic device;

FIG. 2 is a schematic view of the main body and the conventional latch structure coupled thereto;

FIG. 3 is a schematic view of the main body, the conventional latch structure, and a battery before assembly;

FIG. 4 is a schematic view of the main body, the conventional latch structure, and the battery after assembly;

FIG. 5 is another schematic view of the main body, the conventional latch structure, and the battery after assembly;

FIG. 6 is an exploded view of a latch structure and a first body of an electronic device in a preferred embodiment of the present invention;

FIG. 7 is a schematic view of the first body and the latch structure coupled thereto in the preferred embodiment of the present invention;

FIG. 8 is a cross-sectional view of the first body and the latch structure coupled thereto in the preferred embodiment of the present invention;

FIG. 9 is another cross-sectional view of the first body and the latch structure coupled thereto in the preferred embodiment of the present invention;

FIG. 10 is a schematic view of the latch structure, the first body, and a second body of the electronic device before assembly in the preferred embodiment of the present invention;

FIG. 11 is a schematic view of the first and second bodies and the latch structure coupled thereto in the preferred embodiment of the present invention;

FIG. 12 is another schematic view of the first and second bodies and the latch structure coupled thereto in the preferred embodiment of the present invention;

FIG. 13 is an exploded view of the latch structure and the first body in another preferred embodiment of the present invention; and

FIG. 14 is a schematic view of the first and second bodies and the latch structure before assembly in yet another preferred embodiment of the present invention.

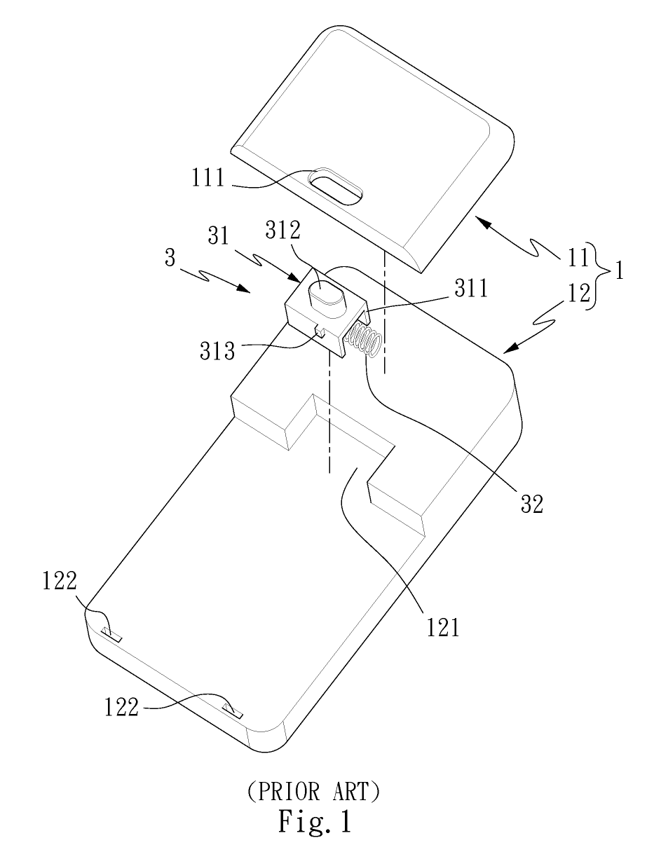

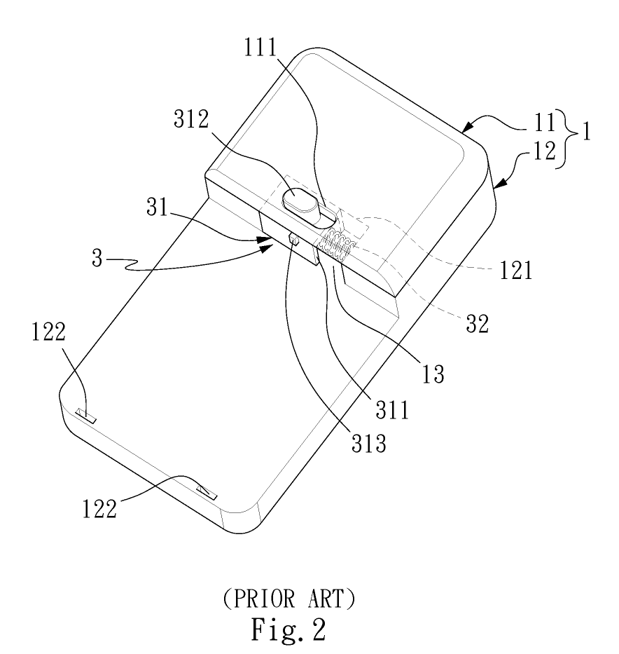

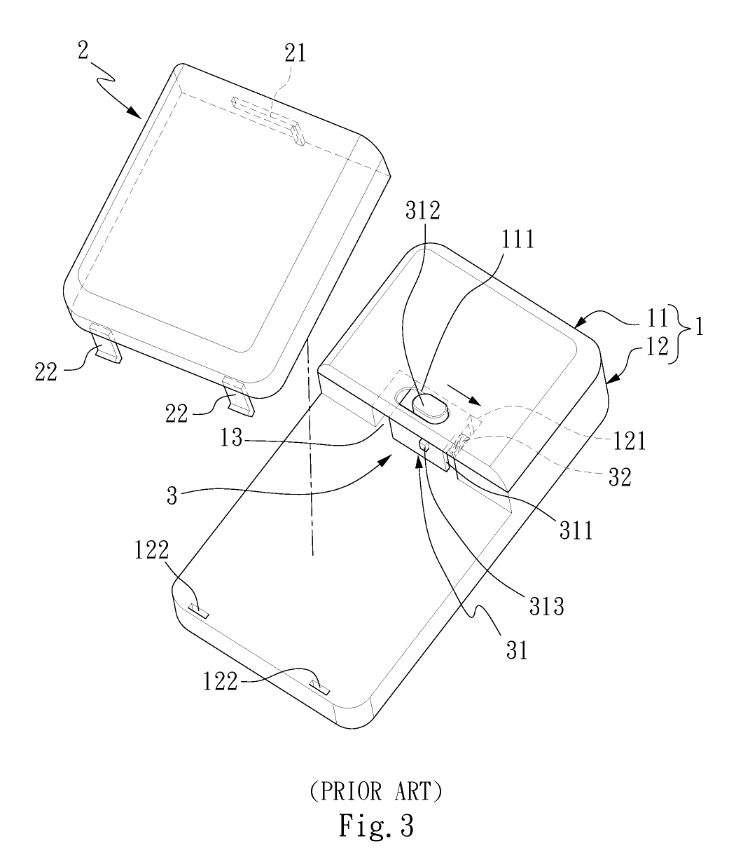

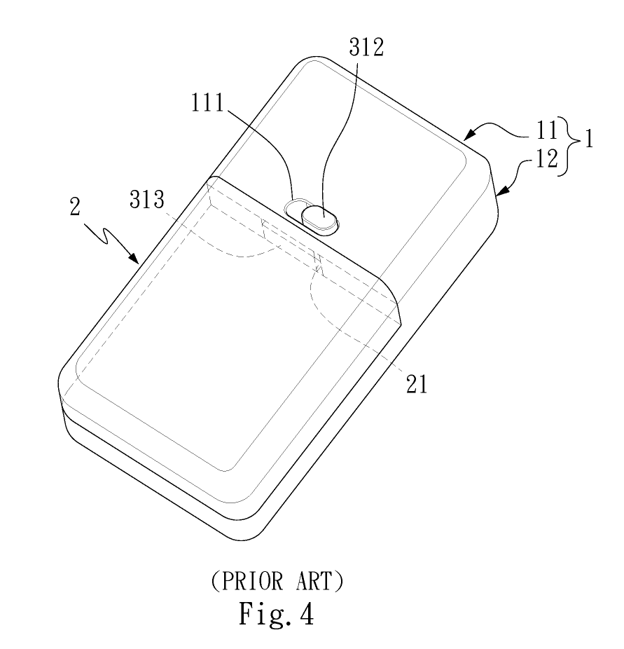

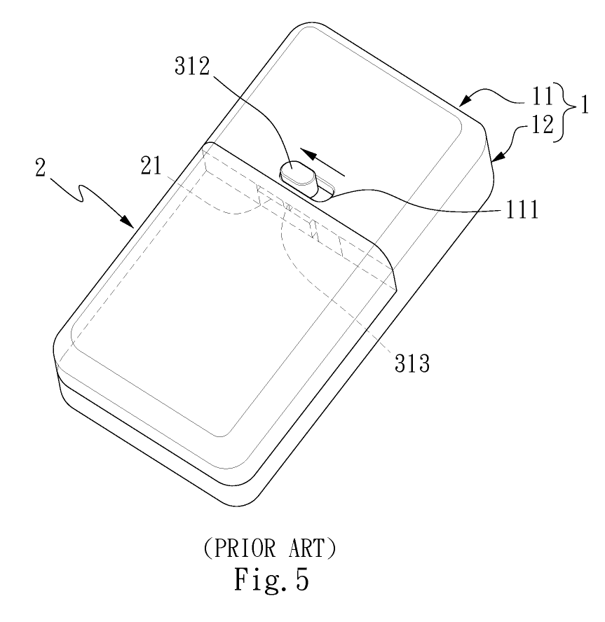

### DETAILED DESCRIPTION

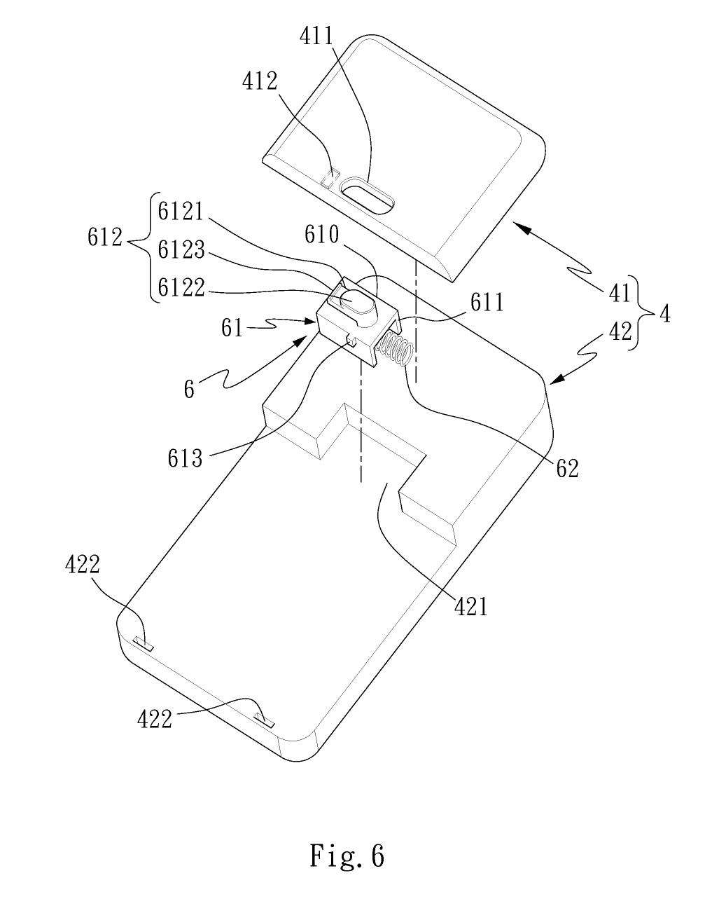

Referring to FIGS. 6 through 8 and FIG. 10, there are shown an exploded view, a schematic view, and a cross-sectional view of a latch structure and a first body of an electronic device, and a schematic view of the latch structure, the first body, and a second body of the electronic device before assembly, in a preferred embodiment of the present invention, respectively. As shown in the drawings, in the first aspect of the present invention, a latch structure 6 is configured to switch a coupling status of a first body 4 and a second body 5 of an electronic device. For example, the first body 4 is a main body, and the second body 5 is a battery. The first body 4 has a receiving unit 43, a coupling unit 412, and a plurality of first coupling units 422. The second body 5 has an L-shaped groove 51 and a plurality of second coupling units 52. The second coupling units 52 are configured to couple with the first coupling units 422, respectively. The latch structure 6 comprises a base 61 and a resilient coupling unit 612. The base 61 has a casing 610 and a resilient element 62. The casing 610 is received in the receiving unit 43 and slidable within the receiving unit 43 in a first direction. The resilient element 62 abuts against an inner wall of the receiving unit 43 and the casing 610, so as to exert a resilient restoring force upon the casing 610 according to the sliding of the casing 610. The casing 610 has a protruding member 613 for coupling with the L-shaped groove 51 so as to couple the first body 4 and the second body 5 together. The resilient coupling unit 612 is disposed on the base 61 and configured to engage the coupling unit 412. Accordingly, in the first aspect of the present invention, the resilient coupling unit 612 of the latch structure 6 enables the latch structure 6 to be fixed to the first body 4, such that the latch structure 6 firmly couples together the first body 4 and the second body 5 of the electronic device. In so doing, separation of the first body 4 and the second body 5 of the electronic device following a fall is unlikely to happen, and little resilience is required for the base 61, because the base 61 just needs resilience that suffices to restore the position of the latch structure 6. Last but not least, the latch structure 6 requires little force to operate.

In the first aspect, the coupling unit 412 is a coupling slot, and the resilient coupling unit 612 has a resilient arm 6121 and a pressing block 6122. The resilient arm 6121 has one end fixed to the base 61 and the other end provided with a coupling block 6123 for coupling with the coupling slot. The other end of the coupling block 6123 is arc-shaped and thus readily couples with the coupling slot. The pressing block 6122 is fixed between the two ends of the resilient arm 6121 and exposed from the first body 4. The coupling block 6123 and the pressing block 6122 are integrally formed as a unitary unit with the resilient arm 6121. The resilient coupling unit 612 is integrally formed as a unitary unit with the base 61.

In the first aspect, the base 61 has the casing 610 and the resilient element 62. The casing 610 has the protruding member 613 protruding therefrom. The protruding member 613 and the resilient element 62 are integrally formed as a unitary unit with the casing 610. Alternatively, the casing 610 has an opening 611. The resilient element 62 has one end abutting against an inner wall of the casing 610 and another end penetrating the opening 611 to abut against an inner wall of the receiving unit 43. The resilient element 62 is a resilient spring.

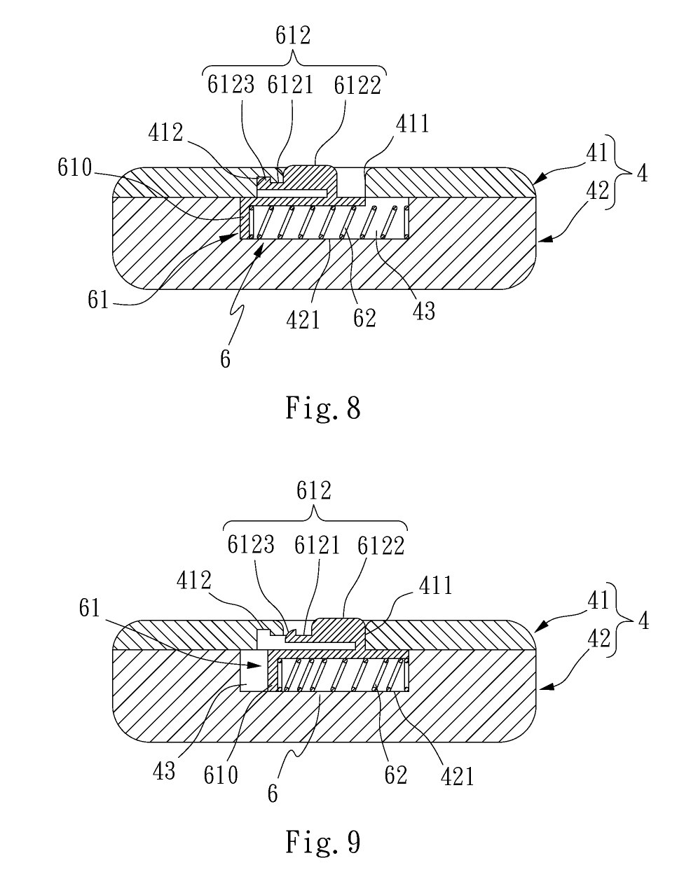

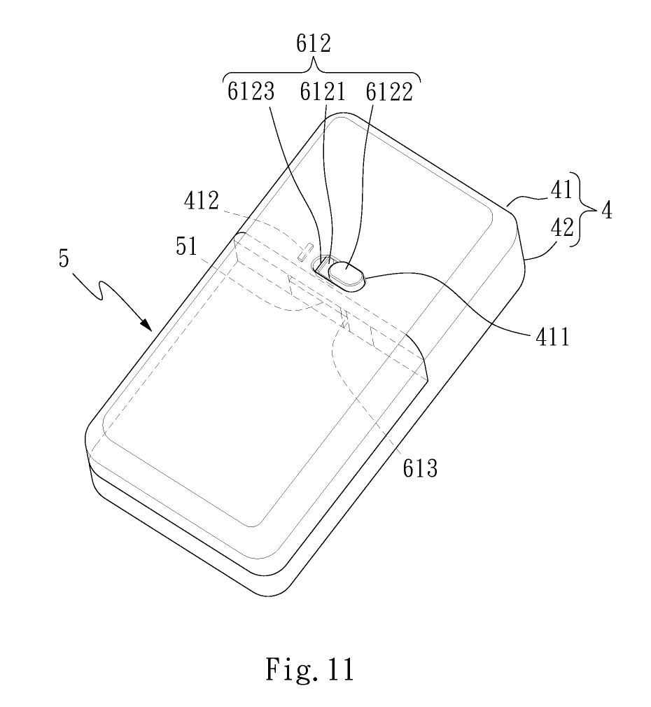

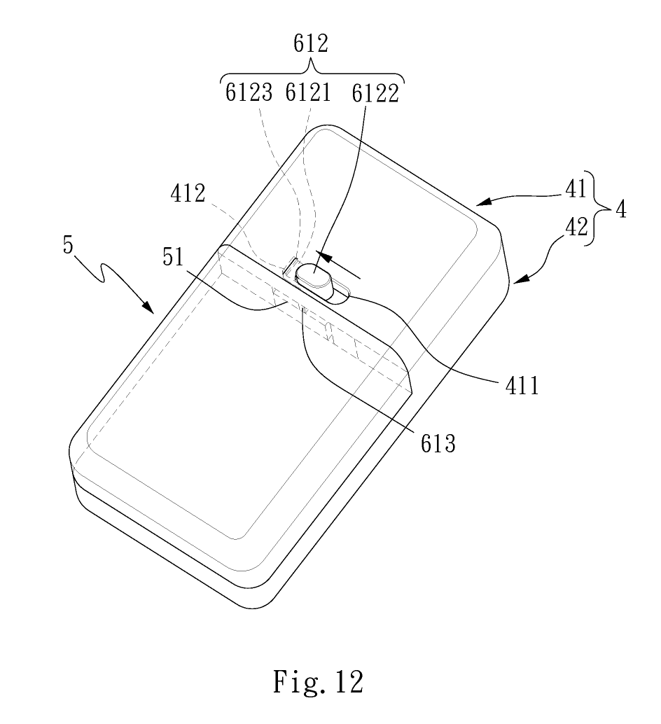

FIGS. 8 through 12 are cross-sectional views of the first body and the latch structure coupled thereto in the preferred embodiment of the present invention, and schematic views of the latch structure, the first body, and a second body of the electronic device before and after assembly in the preferred embodiment of the present invention. As shown in the drawings, in the first aspect of the present invention, to couple together the first body 4 and the second body 5 of the electronic device by means of the latch structure 6, a user has to follow the steps of: pressing the pressing block 6122 of the latch structure 6 such that the resilient arm 6121 rotates about a fixed end thereof to thereby separate the coupling block 6123 at the other end of the resilient arm 6121 from the coupling unit 412 of a cover 41; moving the pressing block 6122 to concurrently enable the lateral displacement of the latch structure 6 and the compression of the resilient element 62; inserting the second coupling units 52 of the second body 5 into the first coupling units 422 of the first body 4, respectively, to thereby couple together the first body 4 and the second body 5 of the electronic device partially; covering the first body 4 with the second body 5 to allow the protruding member 613 of the latch structure 6 to pass through one end of the L-shaped groove 51 of the second body 5; and releasing the pressing block 6122. Completion of the aforesaid steps results in restoring the position of the latch structure 6 by means of the resilient element 62, moving the protruding member 613 of the latch structure 6 to the other end of the L-shaped groove 51, and inserting the coupling block 6123 of the resilient arm 6121 into the coupling unit 412 of the cover 41 again. Eventually, the latch structure 6 is fixed to the first body 4, and, as a result, the second body 5 and the first body 4 are coupled together. Accordingly, the latch structure 6 has advantages below: separation of the first body 4 and the second body 5 of the electronic device following a fall is unlikely to happen; the latch structure 6 can be fixed in position without the resilient element 62, and thus the resilient element 62 suffices to restore the position of the latch structure 6, albeit by a relatively weak degree of resilience; and the latch structure 6 requires little force to operate and thus demonstrates ease of use.

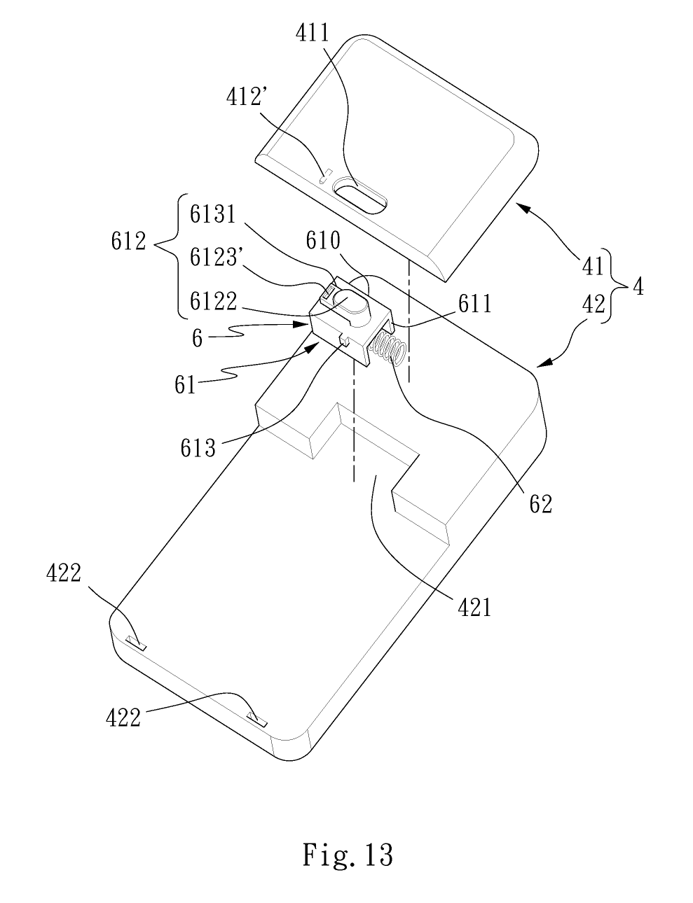

FIG. 13 is an exploded view of the latch structure and the first body in another preferred embodiment of the present invention. As shown in the drawing, in the first aspect of the present invention, a coupling unit 412′ is a coupling block, and the resilient coupling unit 612 has the resilient arm 6121 and the pressing block 6122. The resilient arm 6121 has one end fixed to the base 61 and another end provided with a coupling slot 6123′ for coupling with the coupling block. The other end of the coupling block is arc-shaped and thus readily couples with the coupling slot 6123′. The pressing block 6122 is fixed between the two ends of the resilient arm 6121 and exposed from the first body 4. The coupling slot 6123′ and the pressing block 6122 are integrally formed as a unitary unit with the resilient arm 6121. The resilient coupling unit 612 is integrally formed as a unitary unit with the base 61.

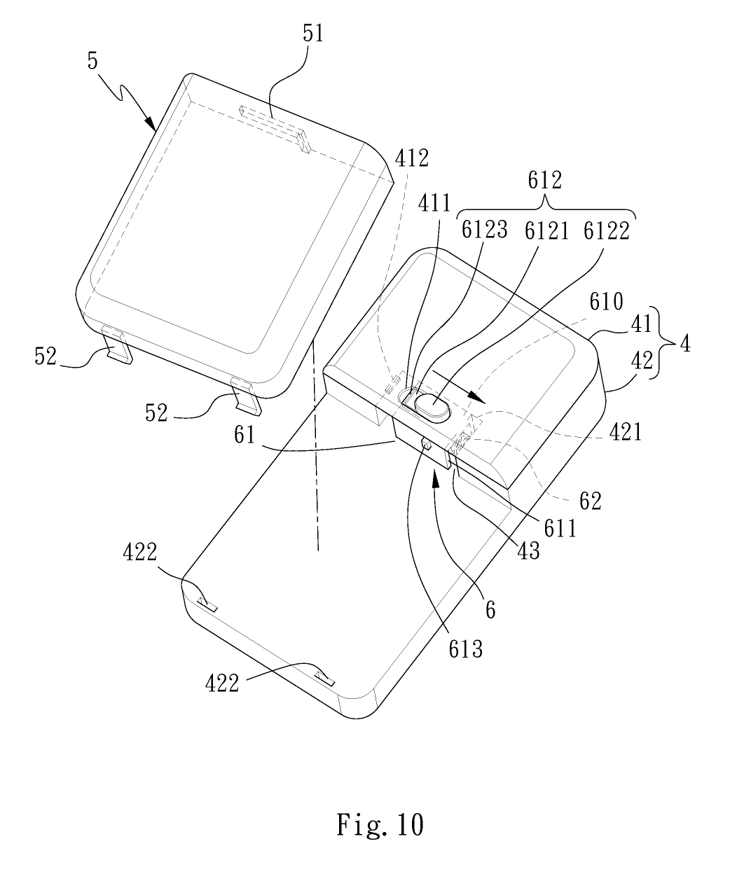

Referring to FIG. 10, there is shown a schematic view of the latch structure, the first body, and the second body before assembly in the preferred embodiment of the present invention. As shown in the drawing, in the second aspect of the present invention, an electronic device comprises the first body 4, the second body 5, the base 61, and the resilient coupling unit 612. The first body 4 has the receiving unit 43 and the coupling unit 412. The second body 5 has the L-shaped groove 51. The base 61 has the casing 610 and the resilient element 62. The casing 610 is received in the receiving unit 43 and is slidable within the receiving unit 43 in the first direction. The resilient element 62 abuts against an inner wall of the receiving unit 43 and the casing 610. The resilient element 62 exerts a resilient restoring force upon the casing 610 according to the sliding of the casing 610. The casing 610 has the protruding member 613 protruding therefrom for coupling with the L-shaped groove 51, so as to couple the first body 4 and the second body 5 together. The resilient coupling unit 612 is disposed on the base 61 and configured to engage the coupling unit 412. Accordingly, in the second aspect of the present invention, the resilient coupling unit 612 of the latch structure 6 enables the latch structure 6 to be fixed to the first body 4, such that the latch structure 6 firmly couples together the first body 4 and the second body 5 of the electronic device. In so doing, separation of the first body 4 and the second body 5 of the electronic device following a fall is unlikely to happen, and little resilience is required for the base 61, because the base 61 just needs resilience that suffices to restore the position of the latch structure 6. Last but not least, the latch structure 6 requires little force to operate.

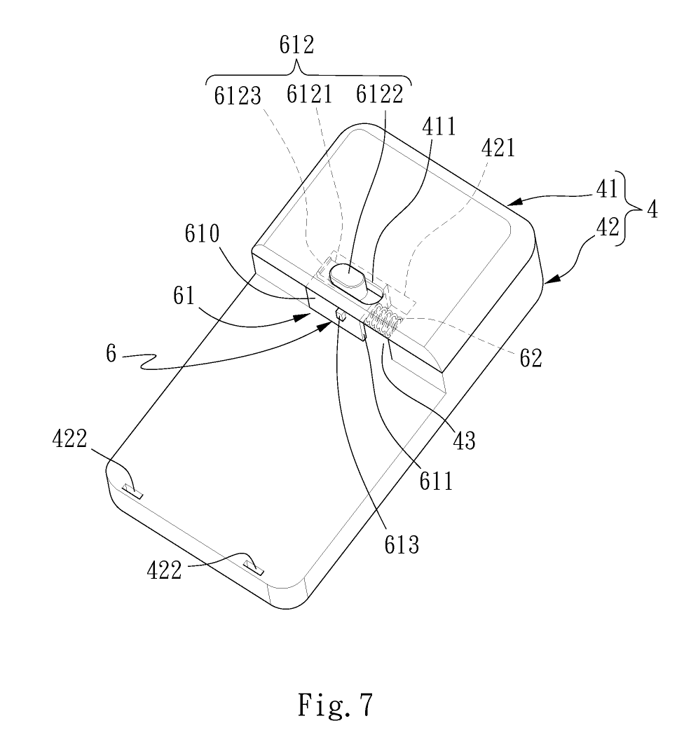

Referring to FIG. 6, there is shown an exploded view of the latch structure and the first body in a preferred embodiment of the present invention. As shown in the drawing, in the second aspect, the first body 4 has the cover 41 and a carrier 42. The carrier 42 has a receiving chamber 421. The first coupling units 422 are formed in the carrier 42. The cover 41 has a through hole 411. The receiving chamber 421 is covered with the cover 41 to form the receiving unit 43. The coupling unit 412 is disposed on the cover 41 and positioned in the receiving unit 43 (shown in FIG. 7). The resilient coupling unit 612 is exposed from the through hole 411. The second body 5 has the second coupling units 52 used to be coupled with the first coupling units 422, respectively. The first coupling units 422 are integrally formed as a unitary unit with the carrier 42. The coupling unit 412 is integrally formed as a unitary unit with the cover 41.

In the second aspect, the first coupling units 422 are coupling slots, and the second coupling units 52 are L-shaped coupling elements. The L-shaped coupling elements can be inserted into the coupling slots so as to couple together the first body 4 and the second body 5 of the electronic device partially.

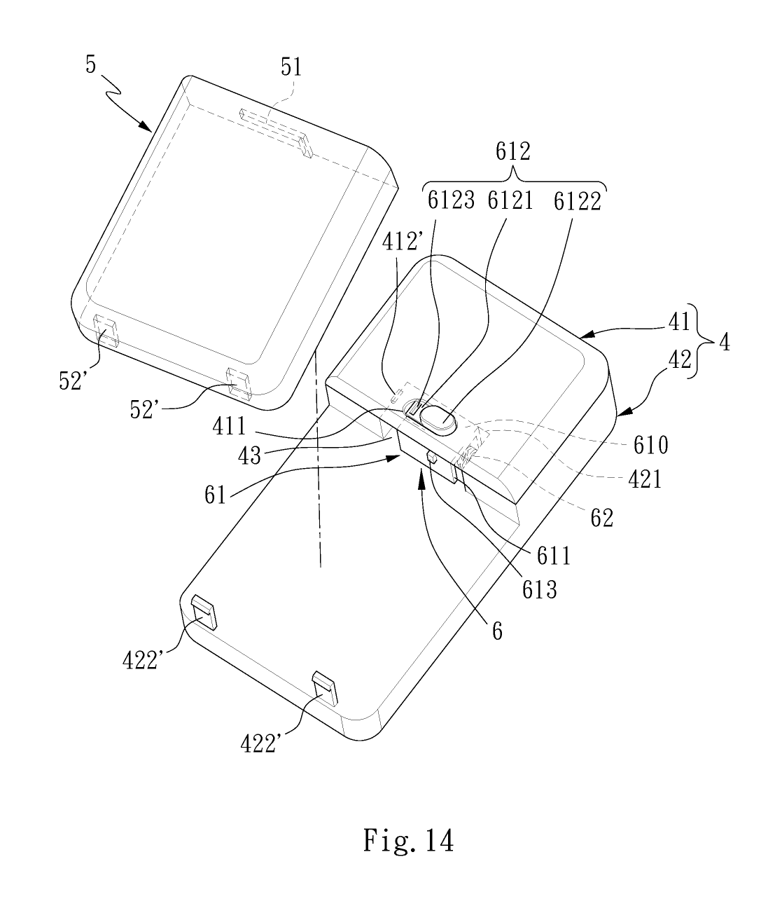

Referring to FIG. 14, there is shown a schematic view of the first and second bodies and the latch structure before assembly in yet another preferred embodiment of the present invention. As shown in the drawing, in the second aspect of the present invention, the first coupling units 422′ are L-shaped coupling elements, and the second coupling units 52′ are coupling slots. The L-shaped coupling elements can be inserted into the coupling slots for coupling together the first body 4 and the second body 5 of the electronic device partially.

In the second aspect, the coupling unit 412 is a coupling slot, and the resilient coupling unit 612 has a resilient arm 6121 and a pressing block 6122. The resilient arm 6121 has one end fixed to the base 61 and the other end provided with a coupling block 6123 for coupling with the coupling slot. The other end of the coupling block 6123 is arc-shaped and thus readily couples with the coupling slot. The pressing block 6122 is fixed between the two ends of the resilient arm 6121 and exposed from the first body 4. The coupling block 6123 and the pressing block 6122 are integrally formed as a unitary unit with the resilient arm 6121. The resilient coupling unit 612 is integrally formed as a unitary unit with the base 61.

FIG. 13 is an exploded view of the latch structure and the first body in another preferred embodiment of the present invention. As shown in the drawing, in the second aspect of the present invention, a coupling unit 412′ is a coupling block, and the resilient coupling unit 612 has the resilient arm 6121 and the pressing block 6122. The resilient arm 6121 has one end fixed to the base 61 and another end provided with a coupling slot 6123′ for coupling with the coupling block. The other end of the coupling block is arc-shaped and thus readily couples with the coupling slot 6123′. The pressing block 6122 is fixed between the two ends of the resilient arm 6121 and exposed from the first body 4. The coupling slot 6123′ and the pressing block 6122 are integrally formed as a unitary unit with the resilient arm 6121. The resilient coupling unit 612 is integrally formed as a unitary unit with the base 61.

FIGS. 8 through 12 are cross-sectional views of the first body and the latch structure coupled thereto in the preferred embodiment of the present invention, and schematic views of the latch structure, the first body, and a second body of the electronic device before and after assembly in the preferred embodiment of the present invention. As shown in the drawings, in the second aspect of the present invention, to couple together the first body 4 and the second body 5 of the electronic device by means of the latch structure 6, a user has to follow the steps of: pressing the pressing block 6122 of the latch structure 6 such that the resilient arm 6121 rotates about a fixed end thereof to thereby separate the coupling block 6123 at the other end of the resilient arm 6121 from the coupling unit 412 of the cover 41; moving the pressing block 6122 to concurrently enable the lateral displacement of the latch structure 6 and the compression of the resilient element 62; inserting the second coupling units 52 of the second body 5 into the first coupling units 422 of the first body 4, respectively, to thereby couple together the first body 4 and the second body 5 of the electronic device partially; covering the first body 4 with the second body 5 to allow the protruding member 613 of the latch structure 6 to pass through one end of the L-shaped groove 51 of the second body 5; and releasing the pressing block 6122. Completion of the aforesaid steps results in restoring the position of the latch structure 6 by means of the resilient element 62, moving the protruding member 613 of the latch structure 6 to the other end of the L-shaped groove 51, and inserting the coupling block 6123 of the resilient arm 6121 into the coupling unit 412 of the cover 41 again. Eventually, the latch structure 6 is fixed to the first body 4, and, as a result, the second body 5 and the first body 4 are coupled together. Accordingly, the latch structure 6 has advantages below: separation of the first body 4 and the second body 5 of the electronic device following a fall is unlikely to happen; the latch structure 6 can be fixed in position without the resilient element 62, and thus the resilient element 62 suffices to restore the position of the latch structure 6, albeit by a relatively weak degree of resilience; and the latch structure 6 requires little force to operate and thus demonstrates ease of use.

The foregoing embodiments are provided to illustrate and disclose the technical features of the present invention so as to enable persons skilled in the art to understand the disclosure of the present invention and implement the present invention accordingly, and are not intended to be restrictive of the scope of the present invention. Hence, all equivalent modifications and variations made to the foregoing embodiments without departing from the spirit and principles in the disclosure of the present invention should fall within the scope of the present invention as set forth in the appended claims.

What is claimed is:

1. A latch structure for switching a coupling status of a first body and a second body of an electronic device, the first body having a receiving unit and a coupling unit, and the second body having an L-shaped groove, the latch structure comprising:
a base having a casing and a resilient element, the casing being received in the receiving unit, being slidable within the receiving unit in a first direction, and having a protruding member for coupling with the L-shaped groove so as to couple the first body and the second body together, and the resilient element abutting against an inner wall of the receiving unit and the casing to thereby exert a resilient restoring force upon the casing according to the sliding of the casing; and
a resilient coupling unit disposed on the base and configured to engage the coupling unit.

2. The latch structure of claim 1, wherein the coupling unit is a coupling slot, and the resilient coupling unit has a resilient arm and a pressing block, the resilient arm having an end fixed to the base and another end provided with a coupling block for coupling with the coupling slot, and the pressing block being fixed between two ends of the resilient arm and exposed from the first body.

3. The latch structure of claim 1, wherein the coupling unit is a coupling block, and the resilient coupling unit has a resilient arm and a pressing block, the resilient arm having an end fixed to the base and another end provided with a coupling slot for coupling with the coupling block, and the pressing block being fixed between two ends of the resilient arm and exposed from the first body.

4. An electronic device, comprising:
a first body having a receiving unit and a coupling unit;
a second body having an L-shaped groove;
a base having a casing and a resilient element, the casing being received in the receiving unit, being slidable within the receiving unit in a first direction, and having a protruding member protruding therefrom for coupling with the L-shaped groove so as to couple the first body and the second body together, and the resilient element abutting against an inner wall of the receiving unit and the casing so as to exert a resilient restoring force upon the casing according to the sliding of the casing; and
a resilient coupling unit disposed on the base and configured to engage the coupling unit.

5. The electronic device of claim 4, wherein the first body has a cover and a carrier, the carrier having a plurality of first coupling units and a receiving chamber, the cover having a through hole and covering the receiving chamber to form the receiving unit, the coupling unit being disposed on the cover and positioned in the receiving unit, the resilient coupling unit being exposed from the through hole, the second body having a plurality of second coupling units, the second coupling units being coupled with the first coupling units, respectively.

6. The electronic device of claim 5, wherein the first coupling units are coupling slots, and the second coupling units are L-shaped coupling elements.

7. The electronic device of claim 5, wherein the first coupling units are L-shaped coupling elements, and the second coupling units are coupling slots.

8. The electronic device of claim 4, wherein the coupling unit is coupling slot, with the resilient coupling unit having a resilient arm and a pressing block, the resilient arm having an end fixed to the base and another end provided with a coupling block for coupling with the coupling slot, and the pressing block being fixed between two ends of the resilient arm and exposed from the first body.

9. The electronic device of claim 4, wherein the coupling unit is a coupling block, with the resilient coupling unit having a resilient arm and a pressing block, the resilient arm having an end fixed to the base and another end provided with a coupling slot for coupling with the coupling block, the pressing block being fixed between two ends of the resilient arm and exposed from the first body.
